(19) United States
(12) Patent Application Publication
(10) Pub. No.: US 2011/0169107 A1
(43) Pub. Date: Jul. 14, 2011

(54) Method for manufacturing a component, method for manufacturing a component system, component, and component system

(76) Inventors: Torsten Kramer, Wannweil (DE); Stefan Pinter, Reutlingen (DE); Hubert Benzel, Pliezhausen (DE); Matthias Illing, Kusterdingen (DE); Frieder Haag, Wannweil (DE); Simon Armbruster, Wannweil (DE)

(21) Appl. No.: 13/054,435

(22) PCT Filed: Jun. 9, 2009
(86) PCT No.: PCT/EP2009/057106

§ 371 Date: Mar. 31, 2011

(30) Foreign Application Priority Data
Jul. 18, 2008 (DE) 10 2008 040 521.3

(51) Int. Cl. H01L 29/84; H01L 21/62

(52) U.S. Cl. 257/415; 438/53

(57) ABSTRACT

A process for manufacturing a component is described. In a first manufacturing step a base structure having a substrate, a diaphragm, and a cavern region is provided. The diaphragm is oriented substantially parallel to a main plane of extension of the substrate. The cavern region is situated between the substrate and the diaphragm, and has an access opening. In a second manufacturing step, a first conductive layer is provided at least partially in the cavern region, in particular on a second side of the diaphragm facing the substrate, perpendicularly to the main plane of extension.

### FIELD OF THE INVENTION

The present invention is directed to a method for manufacturing a component.

### BACKGROUND INFORMATION

Such methods for manufacturing components are believed to be generally understood. For example, a method for manufacturing semiconductor components is discussed in WO 02/02 458 A1, in a first step a first porous layer being formed in the semiconductor component, and in a second step a cavern being formed beneath or out of the first porous layer in the semiconductor component, and the cavern having an access opening.

Furthermore, a method is discussed in the publications DE 10 2004 036 032 A1 and DE 10 2004 036 035 A1 for manufacturing a semiconductor component having a semiconductor substrate, the semiconductor substrate having a diaphragm, a cavern situated at least beneath the diaphragm, and a first doping, and the diaphragm may have an epitaxial layer and being situated on stabilizing elements provided in particular as webs above at least a portion of the cavern.

### SUMMARY OF THE INVENTION

The method according to the present invention for manufacturing a component, the method according to the present invention for manufacturing a component system, the component according to the present invention, and the component system according to the present invention according to the other independent claims have the advantage that the electrically conductive first conductive layer, which is situated in the cavern region and/or on the second side, also referred to below as the “back side,” is to be manufactured using a surface wafer process (SMM), so that a back side coating of comparatively thin diaphragms with the first conductive layer is advantageously possible. In addition, due to the use of a standard process this coating may be manufactured comparatively inexpensively in a surface wafer process. Thus, electrical contacting of the component from the back side of the component and/or a comparatively efficient dissipation of process heat on the back side of the component is particularly possible. The term “diaphragm” within the meaning of the present invention is by no means limited to sensor diaphragms, and also includes any layer which may contain a semiconductor material, which is oriented essentially parallel to the main plane of extension, and/or which is comparatively thin perpendicularly to the main plane of extension.

Advantageous embodiments and refinements of the exemplary embodiments and/or exemplary methods of the present invention are provided in the subclaims and in the description with reference to the drawings.

According to one refinement, it is provided that in the second manufacturing step the first conductive layer is also provided on a first side of the diaphragm facing away from the substrate, perpendicularly to the main plane of extension, the first conductive layer on the first side may be partially connected in a electrically conductive manner to the first conductive layer on the second side, and/or the first conductive layer being structured in the second manufacturing step. Thus, contacting of the first side, also referred to below as the “front side,” from the back side of the diaphragm is possible in a particularly advantageous manner, so that, for example, electrical, electronic, and/or micromechanical structures on the front side may be electrically contacted from the back side.

According to another refinement, it is provided that in the first manufacturing step the cavern region is provided with support structures for supporting the diaphragm, in the second manufacturing step the first conductive layer being applied at least partially to the support structures. The diaphragm is thus stabilized in a particularly advantageous manner, so that on the one hand a much thinner diaphragm may be manufactured and covered on the back side with the first conductive layer, and on the other hand the resolution on the diaphragm for lithographic processes in subsequent manufacturing steps is greatly increased, since back-bending of the diaphragm is prevented. In addition, the support structures allow contacting of the front side on the support structures via the first conductive layer. The support points also prevent first conductive layers on the front side, and/or first conductive layers on the back side, and/or first conductive layers on the front side from growing together with first conductive layers on the back side, so that the first conductive layer advantageously includes a plurality of contact areas which are not electrically connected to one another, thus may allow parallel wiring of the diaphragm.

According to another refinement, it is provided that in a third manufacturing step the diaphragm is separated from the substrate, the diaphragm may be being torn away from the substrate, and the support structures particularly may be caused to break by vibration excitation of the substrate, the diaphragm, and/or the support structures. The detachment of the diaphragm from the substrate allows the component to be manufactured in a wafer composite, the components being separated by detaching the diaphragm from the substrate or from the wafer composite. Tearing off the diaphragm from the substrate may eliminate the need for a sawing process, so that in a particularly advantageous manner no contamination of the component and of the remaining wafer composite results from sawing particles. This is particularly advantageous for comparatively fine, open micromechanical structures, such as for the manufacture of acceleration sensors or yaw rate sensors. In addition, it is possible to reuse the substrate or the wafer, the wafer may be freed of metals, ground, and/or polished beforehand.

According to another refinement, it is provided that in a first substep of the first manufacturing step a microelectronic circuit and/or a micromechanical structure is/are produced in the diaphragm and/or on a first side of the diaphragm facing away from the substrate, and/or in a second substep of the first manufacturing step the access opening is/are etched into the cavern region. The diaphragm particularly may include a monocrystalline semiconductor material, in particular monocrystalline silicon, so that an integrated semiconductor circuit may be advantageously provided in the diaphragm which may be contactable from the back side of the diaphragm. Alternatively, a diaphragm made of polysilicon is provided for implementing micromechanical structures in the diaphragm. In a particularly advantageous manner, components may be implemented which, compared to the related art, are significantly less thick perpendicularly to the main plane of extension.

According to another refinement, it is provided that in a third manufacturing step a first insulating layer is provided on the diaphragm, the cavern region, and/or the support structures, the third manufacturing step may be carried out before the second manufacturing step. Thus, an electrically conductive connection between the diaphragm and the first conductive layer, and therefore a short circuit between the various contact areas, is prevented in a particularly advantageous manner.

According to another refinement, it is provided that in the second manufacturing step the first conductive layer is structured by deposition using shadow masks, in particular with the aid of spray coating, in a first substep of the second manufacturing step a photoresist may be applied to the first conductive layer, in a second substep of the second manufacturing step the photoresist being exposed, in a third substep of the second manufacturing step the photoresist being developed, and in a fourth substep of the second manufacturing step the first conductive layer, i.e., the photoresist, being etched. Structuring of the first conductive layer is thus possible in a particularly advantageous manner, so that in particular a plurality of mutually insulated printed conductors in the first conductive layer, and in particular a plurality of mutually insulated electrical contacts between the front side and the back side, is achievable with the aid of the first conductive layer.

According to another refinement, it is provided that in a fourth manufacturing step subsequent to the second manufacturing step a second conductive layer, in particular a galvanic layer, is provided on the first conductive layer. Thus, in an advantageous manner the conductivity is increased, and the electrical resistance, compared to current conduction, is significantly reduced only in the first layer. The efficiency is greatly increased by such back-side metal plating, in particular for the dissipation of process heat from the component.

According to another refinement, it is provided that in the first manufacturing step a wafer composite having a substrate, a plurality of cavern regions, and a plurality of diaphragms is provided, in the third manufacturing step at least one diaphragm being removed for separating the diaphragm from the wafer composite. Thus, in a particularly advantageous manner a plurality of components is produced at the same time on only a single substrate or wafer, and is not separated until the third manufacturing step. A plurality of components may thus be advantageously produced at the same time, and therefore in a particularly cost-effective and time-saving manner.

A further subject matter of the exemplary embodiments and/or exemplary methods of the present invention is a method for manufacturing a component system having a component according to the present invention, in a fifth manufacturing step subsequent to the third manufacturing step the component being provided on a further component and/or on a carrier element, in particular on a printed circuit board and/or in a housing, and may be soldered, bonded, and/or glued, and the component and in particular the integrated circuit and/or the micromechanical structure being electrically contacted with the aid of the first and/or the second conductive layer. Due to the first conductive layer on the back side, butt-jointed soldering, bonding, and/or gluing of the component to the further component and/or to the carrier element, similarly as for a surface mounted device (SMD) component in a surface mounting technology (SMT) method, is possible in a particularly cost-effective manner, since no additional contacting steps for electrically contacting the component are necessary. The contact areas may be directly provided in an electrically conductive manner on connecting surfaces and/or printed conductors of the further component and/or of the carrier element. As a result of providing the component on a what may be a similarly or identically configured further component, a plurality of stacked microchips may be produced in a particularly simple manner, it being advantageously possible to achieve comparatively low stack heights of the stacked microchips due to the comparatively small thicknesses of the diaphragms.

A further subject matter of the present invention is a component, the component having the diaphragm, and the first conductive layer being situated in the cavern region and in particular on the second side. As described above in detail, the component may have a comparatively thin diaphragm, at the same time it being possible to efficiently dissipate heat via the first conductive layer and/or to electrically contact the component from the back side due to the first conductive layer being situated on the back side.

According to one refinement, it is provided that the first conductive layer is also situated on the first side, the first conductive layer may include at least one electrically conductive contact between the first side and the cavern region, and in particular between the first side and the second side. Thus, structures on the front side of the component or of the diaphragm may be electrically contacted from the back side in a particularly advantageous manner, so that, after separation as an SMD component, the component may be mounted, for example, directly on connecting surfaces of a carrier element in an electrically conductive manner.

According to another refinement, it is provided that the diaphragm has a microelectronic circuit and/or a micromechanical structure which may be contacted from the cavern region and/or from the second side, in particular with the aid of the at least one electrically conductive contact. Thus, in a particularly advantageous manner the component may include an integrated microchip and/or a sensor, particularly may be a yaw rate sensor, an acceleration sensor, and/or a pressure sensor.

A further subject matter of the present invention is a component system, the component being situated on the further component and/or on the carrier element, and in particular being soldered, glued, and/or bonded, and the carrier element may include a printed circuit board and/or a housing. The component may be particularly advantageously electrically contacted and controlled in a comparatively simple manner.

According to one refinement, it is provided that the component is situated essentially congruently on the further component, in particular perpendicularly to the main plane of extension, and a further electrically conductive contact of the further component particularly may be connected to the corresponding electrically conductive contact of the component in an electrically conductive manner. Component stacks may thus be formed in a particularly advantageous manner; as a result of the first conductive layer on the back side of each component, the stacked components may be electrically contacted comparatively easily, and the stack height is comparatively small in a particularly advantageous manner due to the comparatively thin diaphragm of each component perpendicularly to the main plane of extension.

Exemplary embodiments of the present invention are illustrated in the drawings and explained in greater detail in the following description.

### BRIEF DESCRIPTION OF THE DRAWINGS

FIG. 1a shows a schematic side view of a first precursor structure for manufacturing a component according to a first specific embodiment of the present invention.

FIG. 1b shows a schematic top view of a first precursor structure for manufacturing a component according to a first specific embodiment of the present invention.

FIG. 2 shows a schematic side view of a second precursor structure for manufacturing a component according to the first specific embodiment of the present invention.

FIG. 3a shows a schematic side view of a third precursor structure for manufacturing a component according to the first specific embodiment of the present invention.

FIG. 3b shows a schematic top view of a third precursor structure for manufacturing a component according to the first specific embodiment of the present invention.

FIG. 4 shows a schematic side view of a fourth precursor structure for manufacturing a component according to the first specific embodiment of the present invention.

FIG. 5 shows a schematic partial side view of a fifth precursor structure for manufacturing a component according to the first specific embodiment of the present invention.

FIG. 6 shows a schematic side view of a sixth precursor structure for manufacturing a component according to the first specific embodiment of the present invention.

FIG. 7 shows a schematic partial side view of a seventh precursor structure for manufacturing a component according to the first specific embodiment of the present invention.

FIG. 8 shows a schematic side view of a wafer composite having two components according to the first specific embodiment of the present invention.

FIG. 9 shows a schematic side view of an eighth precursor structure for manufacturing a component system according to a first specific embodiment of the present invention.

FIG. 10 shows a schematic side view of a component system according to the first specific embodiment of the present invention.

FIG. 11 shows a schematic side view of a component system according to a second specific embodiment of the present invention.

### DETAILED DESCRIPTION

In the figures, identical parts having reference numerals are always provided with the same reference numerals, and in each case are therefore generally named or mentioned only once.

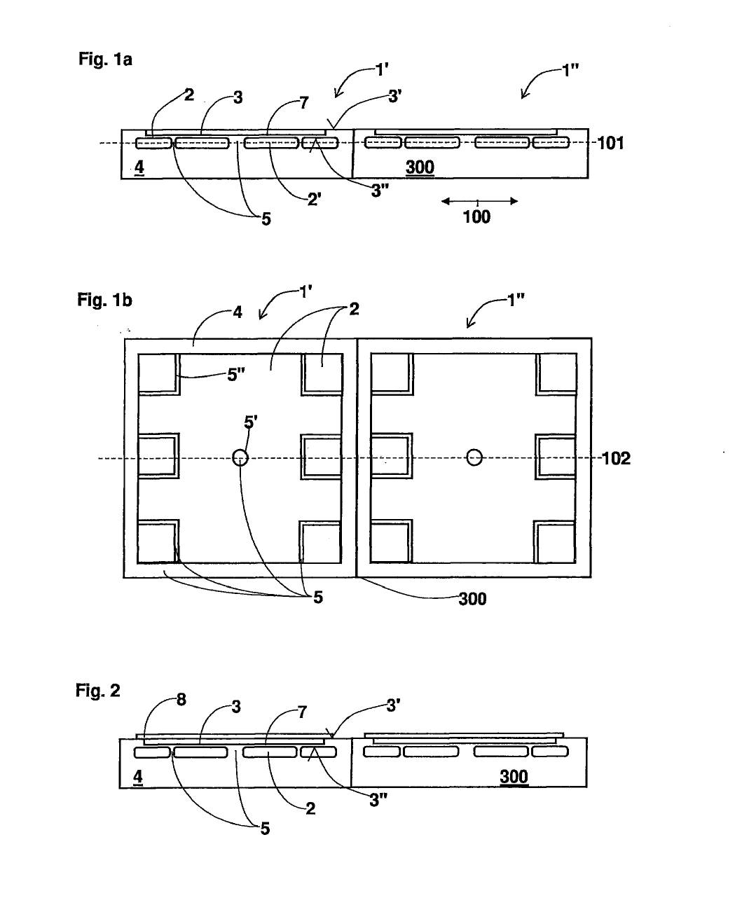

FIGS. 1a and 1b illustrate a schematic side view and a schematic top view, respectively, of a first precursor structure for manufacturing a component according to a first specific embodiment of the present invention, part of the first manufacturing step for partial production of base structure 1′ being illustrated with reference to FIGS. 1a and 1b, and FIG. 1a including a sectional illustration of

FIG. 1b along a first intersecting line 102. The first precursor structure has a partial base structure 1′ in a wafer composite 300 together with further partial base structures 1″, partial base structure 1′ having a substrate 4, a diaphragm 3, and a cavern region 2, and diaphragm 3 being oriented essentially parallel to a main plane of extension 100 of substrate 4, and cavern region 2 being situated between substrate 4 and diaphragm 3. Cavern region 2 also has support structures 5 which extend perpendicularly to main plane of extension 100 and, for supporting diaphragm 3, on a second side 3″, also referred to below as back side 3″, of diaphragm 3 and/or of component 1, diaphragm 3 is connected to substrate 4, so that a plurality of caverns 2′ separated from one another by support structures 5 is formed in cavern region 2, parallel to main plane of extension 100. The shape, number, and position of support structures 5 may be arbitrarily selected, which may be at least one support structure 5′ having a diameter which is essentially equal to the thickness of diaphragm 3 perpendicularly to main plane of extension 100. It is apparent from FIG. 1b that a plurality of support structures 5 is provided as narrow support walls 5″; each of support walls 5″ may include a bond pad, to be subsequently provided, on back side 3″. Second side 3″ is a side of diaphragm 3 facing substrate 4. On a first side 3′ of diaphragm 3, also referred to below as front side 3′, of diaphragm 3 and/or of component 1, opposite from second side 3″ and perpendicularly to main plane of extension 100, diaphragm 3 has an integrated circuit 7 which may have printed conductors and further bond pads. The first precursor structure is produced using surface micromechanics (OMM) technology, which may be done by using an advanced porous silicon membrane (APSM) process or a known sacrificial layer process, for example using sacrificial oxide and polysilicon structures, similarly as for a controlled metal buildup (CMB) process. The APSM process is described in the related art. Substrate 4 and diaphragm 3 may include silicon, particularly may be monocrystalline silicon.

FIG. 2 illustrates a schematic side view of a second precursor structure for manufacturing a component 1 according to the first specific embodiment of the present invention, part of the first manufacturing step for partial production of base structure 1′ being illustrated with reference to FIG. 2, and the second precursor structure being essentially identical to the first precursor structure illustrated in FIG. 1a; in the first manufacturing step a structured trench mask 8, which in particular covers integrated circuit 7, is provided on front side 3′ of diaphragm 3. Trench mask 8 includes in particular a structured resist or an oxide layer, for example TEOS.

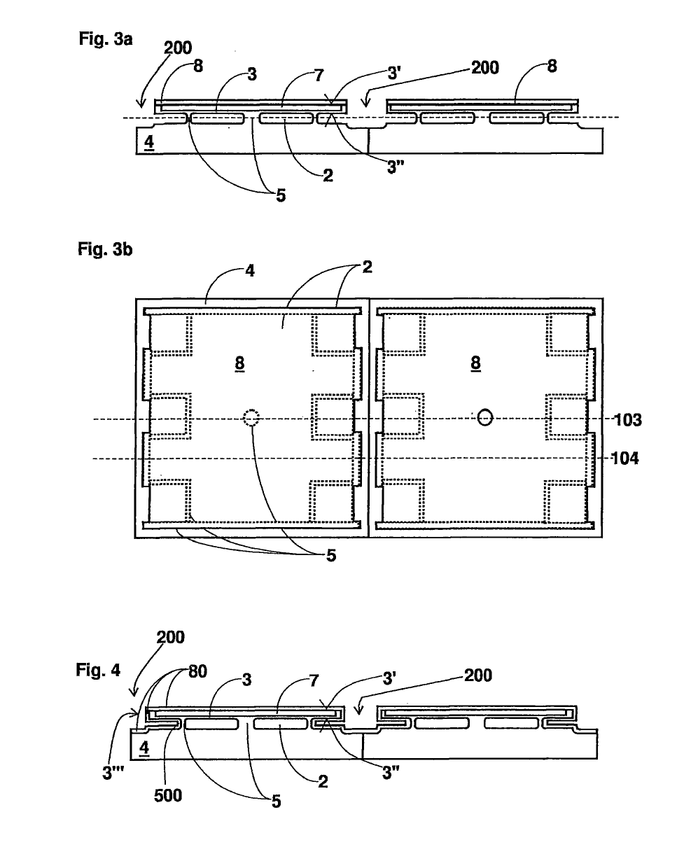

FIGS. 3a and 3b illustrate a schematic side view and a schematic top view, respectively, of a third precursor structure for manufacturing a component according to the first specific embodiment of the present invention, third precursor structure corresponding to a base structure 1′″ for manufacturing component 1, and the third precursor structure being identical to the second precursor structure illustrated in FIG. 2; in the first manufacturing step the third precursor structure is etched at the opened locations in the structured trench mask 8, so that diaphragm 3 is connected to substrate 4 solely via support structures 5 beneath diaphragm 3, and cavern region 2 has access openings 200 which face front side 3′. The structures and elements concealed by trench mask 8 are illustrated in dashed lines in FIG. 3b for the sake of clarity.

FIG. 4 illustrates a schematic side view of a fourth precursor structure for manufacturing a component 1 according to the first specific embodiment of the present invention, FIG. 4 essentially corresponding to a sectional illustration of FIG. 3b along a second intersecting line 103, and a third manufacturing step being illustrated with reference to the fourth precursor structure; an insulating layer 80 is applied to the third precursor structure which covers diaphragm 3 on the front side 3′ and trench mask 8, and is also situated on support structures 5, on back side 3″ of diaphragm 3, on side regions 3″′ perpendicularly to main plane of extension 100 between front and back sides 3′, 3″ of diaphragm 3, and on substrate 4, in each case in cavern regions 2 in caverns 2′ having access openings 200.

FIG. 5 illustrates a schematic partial side view of a fifth precursor structure for manufacturing a component 1 according to the first specific embodiment of the present invention, the partial side view including an enlargement of a partial region of the fourth precursor structure illustrated in FIG. 4, and the fifth precursor structure being essentially identical to the fourth precursor structure; a second and a fourth manufacturing step are illustrated with reference to the fifth precursor structure, in the second manufacturing step a first conductive layer 6 being provided, at least partially, on insulating layer 80, and in the fourth manufacturing step a second conductive layer 6′ being provided, at least partially, on first conductive layer 6. First conductive layer 6′ is situated at least partially on front side 3′, on back side 3″, on side regions 3″′, on support structures 5, and on substrate 4. First conductive layer 6 in particular includes a plurality of first partial conductive layers which are electrically insulated from one another, and which in the region of each bond pad may include an electrically conductive connection between a first partial conductive layer on back side 3″ and a first partial conductive layer on front side 3′ via a first partial conductive layer at corresponding side regions 3″′. The first metal layer may be connected in an electrically conductive manner to integrated circuit 7 on front side 3′, and has the function of electrically contacting integrated circuit 7 on front side 3′, from back side 3″. First conductive layer 6 is formed, for example, by sputtering or vapor deposition or by chemical deposition of metal, and then structured. The structuring is carried out using a spray etching process, for example. For the structuring of first conductive layer 6, the second manufacturing step particularly may include a first substep in which a photoresist is applied to first conductive layer 6, a second substep in which the photoresist is exposed, a third substep in which the photoresist is developed, and a fourth substep in which first conductive layer 6, i.e., the photoresist, is etched. Second conductive layer 6′ is deposited, at least partially, on first conductive layer 6, substrate 4, and/or diaphragm 3, using an electroplating process. First and/or second conductive layer 6, 6′ may include a metal.

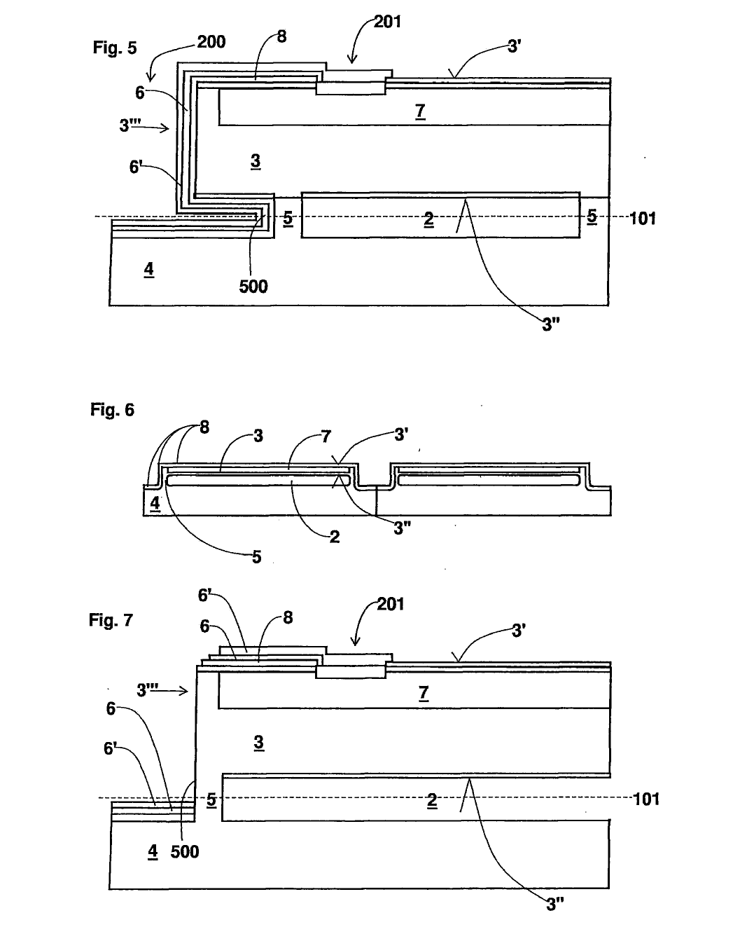

FIG. 6 illustrates a schematic side view of a sixth precursor structure for manufacturing a component 1 according to the first specific embodiment of the present invention, the sixth precursor structure being identical to the fourth precursor structure illustrated in FIG. 4, except that FIG. 6 essentially corresponds to a sectional illustration of FIG. 3b along a third intersecting line 104, and not along second intersecting line 103 according to FIG. 4; the third manufacturing step for applying insulating layer 80 to the third precursor structure is likewise illustrated with reference to the sixth precursor structure, in contrast to FIG. 4 no bond pads being situated in the edge region of diaphragm 3, and instead diaphragm 3 being connected at the edge to substrate 4 via a support structure 5″′, and therefore no cavern 2′ in cavern region 2, having an access opening 200 for penetration of insulating layer 80, being illustrated in FIG. 6. Therefore, in FIG. 6 insulating layer 80 is provided only on front side 3′ of diaphragm 3 and on trench mask 8, in side region 3′″ of diaphragm 3, on an outer side 500 of support structure 5 which is exposed toward front side 3′, and on substrate 4 which is exposed toward front side 3′.

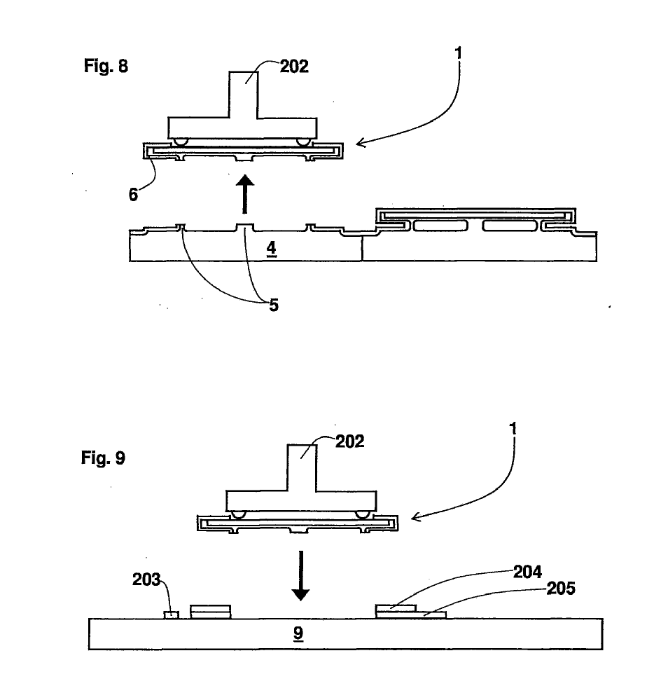

FIG. 7 illustrates a schematic partial side view of a seventh precursor structure for manufacturing a component according to the first specific embodiment of the present invention, the seventh precursor structure being identical to the fifth precursor structure illustrated in FIG. 5, except that FIG. 7 corresponds to the fifth precursor structure illustrated along third intersecting line 104, and not along second intersecting line 103; with reference to the seventh precursor structure the second and fourth manufacturing steps for applying first and second conductive layer 6, 6′ to the fourth and seventh precursor structures likewise being illustrated; in contrast to FIG. 5, no first and second conductive layers 6, 6′ are provided on side region 3″ of diaphragm 3 and on outer side 500 of support structure 5, so that the electrical contacts between front side 3′ and back side 3″ in the form of the first partial conductive layers, first conductive layer 6, and/or second conductive layer 6′ are electrically insulated from one another. The fifth and seventh precursor structures include in particular component 1 according to the first specific embodiment of the present invention.

FIG. 8 illustrates a schematic side view of a wafer composite 300 having a component 1 according to the first specific embodiment of the present invention; FIG. 8 illustrates a third manufacturing step in which diaphragm 3, i.e., component 1 according to the first specific embodiment, is separated from substrate 4 and thus removed from wafer composite 300. For this purpose, diaphragm 3, i.e., component 1, is “picked off” or broken off from substrate 4, i.e., wafer composite 300, using a tool 202, causing support structures 5 to break. This breakage of support structures 5 may be assisted by a vibrating motion of a removal head of tool 202, the vibrating motion particularly may include ultrasonic vibrations in an x, y, and/or z direction and/or torsional vibrations in an x, y, and/or z plane.

FIG. 9 illustrates a schematic side view of an eighth precursor structure for manufacturing a component system 10 according to a first specific embodiment of the present invention; a fifth manufacturing step is illustrated with reference to the eighth precursor structure, in which tool 202 illustrated in FIG. 8 is used to place component 1 on a carrier element 9 in the form of a printed circuit board, which may be a ceramic or liquid crystalline polymer (LCP) board. Printed conductors 205 are provided on carrier element 9, and solder 204 is provided on printed conductors 205. For electrical contacting and mechanical fixing of component 1 to carrier element 9, component 1 is placed on carrier element 9 in such a way that, via solder 204, a connection which is electrically conductive and resistant to mechanical stress is established between printed conductors 205 or connecting surfaces of printed conductors 205 and the corresponding bond pads of component 3, the bond pads including first and/or second conductive layer 6, 6′ and/or the partial conductive layer on back side 3″ of diaphragm 3. In particular, further printed conductors 203 and/or further electrical, electronic, and/or microelectronic elements are provided on carrier element 9. Alternatively, in the fifth manufacturing step component 1 is dipped into a solder bath and the bond pads are soldered to printed conductors 203. In another alternative, component 1 is glued to printed conductors 203 with the aid of a conductive adhesive, the conductive adhesive may be applied to the back side of component 1 and/or to carrier element 9, particularly may be done by screen printing, pad printing, and/or dispensing.

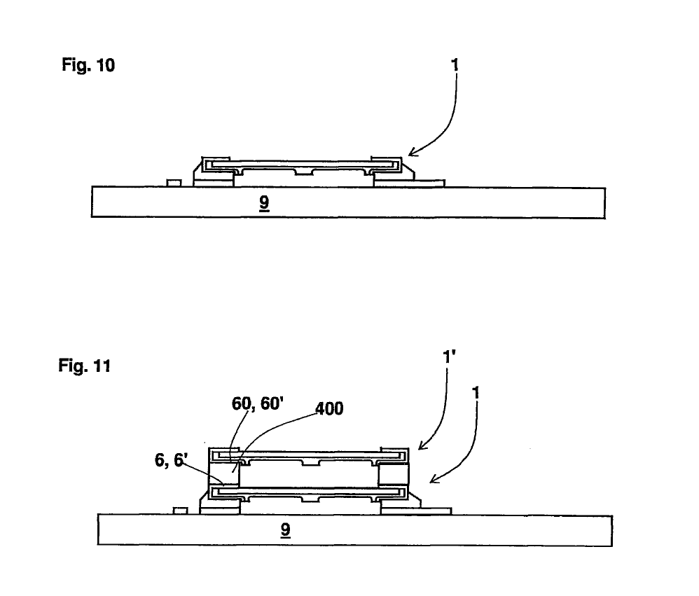

FIG. 10 illustrates a schematic side view of a component system 10 according to the first specific embodiment of the present invention; component system 10 includes component 1 according to the first specific embodiment situated on carrier element 9, and component system 10 has electrically conductive contact between integrated circuit 7 on comparatively thin diaphragm 3 and printed conductors 205 of carrier element 9 with the aid of first conductive layer 6, second conductive layer 6′, a partial conductive layer, and/or a bond pad on back side 3″ of diaphragm 3; first conductive layer 6, second conductive layer 6′, the partial conductive layer, and/or the bond pad are connected on back side 3″ of diaphragm 3 to printed conductors 205 via a solder connection in a manner which is resistant to mechanical stress and electrically conductive.

FIG. 11 illustrates a schematic side view of a component system 10 according to a second specific embodiment of the present invention, the second specific embodiment being essentially identical to the first specific embodiment illustrated in FIG. 10, and on a side of component 1 facing away from carrier element 9 a further component 1′ is provided on component 1 in such a way that, between further component 1′ and carrier element 9, component 1 is oriented perpendicularly to main plane of extension 100, congruent with further component 1′. Further component 1′ which may have the same design as component 1, and further first conductive layers 60, further second conductive layers 60′, further partial conductive layers, and/or further bond pads at further back side 3″ of further component 1′ are connected in particular via conductive connecting elements 400 to further bond pads, the partial conductive layer, first conductive layers 6, and/or second conductive layers 6′ at front side 3′ of component 1 in a manner which is electrically conductive and resistant to mechanical stress, so that component 1 as well as further component 1′ may be contacted by carrier element 9. It is conceivable for component system 10 according to the second specific embodiment to be expanded by a plurality of further components 1′, thus providing a superposed stack of a plurality of congruently situated further components 1′ perpendicularly to main plane of extension 100.

1-15. (canceled)

16. A method for manufacturing a component, the method comprising:
(a) providing a base structure including a substrate, a diaphragm, and a cavern region, wherein the diaphragm is oriented substantially parallel to a main plane of extension of the substrate, the cavern region is situated between the substrate and the diaphragm, and the cavern region has an access opening;
(b) providing a first conductive layer at least partially in the cavern region, in particular on a second side of the diaphragm facing the substrate, perpendicularly to the main plane of extension; and
(c) separating the diaphragm from the substrate.

17. The method of claim 16, wherein the first conductive layer is also provided on a first side of the diaphragm facing away from the substrate perpendicularly to the main plane of extension, and wherein the first conductive layer on the first side is partially connected in an electrically conductive manner to the first conductive layer on the second side.

18. The method of claim 16, wherein the cavern region is provided with support structures for supporting the diaphragm, and wherein the first conductive layer is applied at least partially to the support structures.

19. The method of claim 16, wherein at least one of the following is performed: (i) in a first substep of step (a), producing at least one of a microelectronic circuit and a micromechanical structure in at least one of the diaphragm and on a first side of the diaphragm facing away from the substrate, and (ii) in a second substep of step (a), etching the access opening into the cavern region.

20. The method of claim 16, further comprising:
providing a first insulating layer on at least one of the diaphragm, the cavern region, and the support structures, wherein the providing of the first insulating layer is carried out before performing step (b).

21. The method of claim 16, wherein in step (b), the first conductive layer is structured by deposition using shadow masks, with the aid of spray coating, by performing the following: in a first substep of step (b), applying a photoresist to the first conductive layer, in a second substep of step (b), exposing the photoresist, in a third substep of step (b), developing the photoresist, and in a fourth substep of step (b), etching the photoresist of the first conductive layer.

22. The method of claim 16, further comprising:
(d) subsequent to step (b), providing a second conductive layer, which is a galvanic layer, on the first conductive layer.

23. The method of claim 16, wherein in step (a), a wafer composite (300) having a substrate, a plurality of cavern regions, and a plurality of diaphragms are provided, and wherein in step (c), at least one diaphragm is removed from the wafer composite for separating the diaphragm.

24. A method for manufacturing a component system having a component, the method comprising:
(i) making a component by performing the following:
(a) providing a base structure including a substrate, a diaphragm, and a cavern region, wherein the diaphragm is oriented substantially parallel to a main plane of extension of the substrate, the cavern region is situated between the substrate and the diaphragm, and the cavern region has an access opening;
(b) providing a first conductive layer at least partially in the cavern region, in particular on a second side of the diaphragm facing the substrate, perpendicularly to the main plane of extension; and
(c) separating the diaphragm from the substrate;
(ii) subsequent to step (c), providing the component on at least one of a further component and on a carrier element, in particular on at least one of a printed circuit board and in a housing, and being at least one of soldered, bonded, and glued, the at least one of the microelectronic circuit and the micromechanical structure is electrically contacted with the aid of at least one of the first conductive layer and the second conductive layer.

25. A component, comprising:
a component having a diaphragm, wherein a first conductive layer is situated in a cavern region and in particular on a second side of the diaphragm;
wherein the component is made by performing the following:
(a) providing a base structure including a substrate, a diaphragm, and the cavern region, wherein the diaphragm is oriented substantially parallel to a main plane of extension of the substrate, the cavern region is situated between the substrate and the diaphragm, and the cavern region has an access opening;
(b) providing the first conductive layer at least partially in the cavern region, in particular on the second side of the diaphragm facing the substrate, perpendicularly to the main plane of extension; and
(c) separating the diaphragm from the substrate.

26. The component of claim 25, wherein the first conductive layer is also situated on the first side, the first conductive layer including at least one electrically conductive contact between the first side and the cavern region, and in particular between the first side and the second side.

27. The component of claim 25, wherein the diaphragm has at least one of a microelectronic circuit and a micromechanical structure which is contactable from at least one of the cavern region and from the second side, in particular with the aid of the at least one electrically conductive contact.

28. A component system, comprising:
a component;
a further component, wherein the component is situated on at least one of the further component and on a carrier element, and in particular is at least one of soldered, glued, and bonded, and wherein the carrier element includes at least one of a printed circuit board and a housing;
wherein the component is made by performing the following:
(a) providing a base structure including a substrate, a diaphragm, and a cavern region, wherein the diaphragm is oriented substantially parallel to a main plane of extension of the substrate, the cavern region is situated between the substrate and the diaphragm, and the cavern region has an access opening;
(b) providing a first conductive layer at least partially in the cavern region, in particular on a second side of the diaphragm facing the substrate, perpendicularly to the main plane of extension; and
(c) separating the diaphragm from the substrate.

14. The component system of claim 28, wherein the component is situated essentially congruently on the further component, in particular perpendicularly to the main plane of extension, and a further electrically conductive contact of the further component is connected to the corresponding electrically conductive contact of the component in an electrically conductive manner.

30. The method of claim 16, wherein the diaphragm is torn away from the substrate, and the support structures are caused to break by vibration excitation of at least one of the substrate, the diaphragm, and the support structures.
